(19) United States
(12) Patent Application Publication
(10) Pub. No.: US 2025/0261434 A1
(43) Pub. Date: Aug. 14, 2025

(54) LOW RESISTANCE FEEDTHROUGH CELL WITH CONTACTED POLY PITCH BY METAL GATE CONNECTED TO FEEDTHROUGH VIA

(71) Applicant: Taiwan Semiconductor Manufacturing Co., Ltd., Hsinchu (TW)

(72) Inventors: Chun-Yuan CHEN, Hsinchu (TW); Huan-Chieh SU, Hsinchu (TW); Chih-Hao WANG, Hsinchu (TW)

(21) Appl. No.: 18/778,680

(22) Filed: Jul. 19, 2024

Related U.S. Application Data
(60) Provisional application No. 63/553,025, filed on Feb. 13, 2024.

(51) Int. Cl. H01L 21/8234; H01L 21/768; H01L 23/522; H01L 23/528; H01L 27/088; H01L 29/06; H01L 29/423; H01L 29/66; H01L 29/775; H01L 29/786

(52) U.S. Cl. CPC H10D 84/038; H01L 21/76898; H01L 23/5226; H01L 23/5286; H10D 64/017; H10D 84/0149; H10D 84/83; H10D 30/014; H10D 30/43; H10D 30/6735; H10D 30/6757; H10D 62/121

(57) ABSTRACT

An integrated circuit includes a feedthrough via structure includes a dummy transistor with a dummy gate metal. The dummy transistor is positioned between a first transistor and a second transistor. The dummy gate metal is a different material than the gate metal of the first and second transistors. The feedthrough via structure and electrically connects a backside metal line with a front side metal line. The first and second transistors are positioned between the front side of backside metal lines.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-21B are cross-sectional views, perspective, and top views of an integrated circuit at various stages of processing, in accordance with some embodiments.

FIG. 22 is a flow diagram of a method for operating an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

Embodiments of the disclosure provide an integrated circuit with a feedthrough via structure that provides an electrical connection between the backside metal lines and front side metal lines of the integrated circuit. The feedthrough via structure merges dummy source/drain contacts, a dummy metal, and source/drain conductive vias. The dummy metal is formed in place of a gate metal of a gate all around transistor structure positioned between two continuous poly diffusion edge (CPODE) structures. The result is a feedthrough cell with low area penalty and low resistance. This results in improved processing speeds and reduced power consumption.

The feedthrough via structure may be positioned between transistors. The transistors may be termed “nanostructure transistors” and the channels may be termed “semiconductor nanostructures”. The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

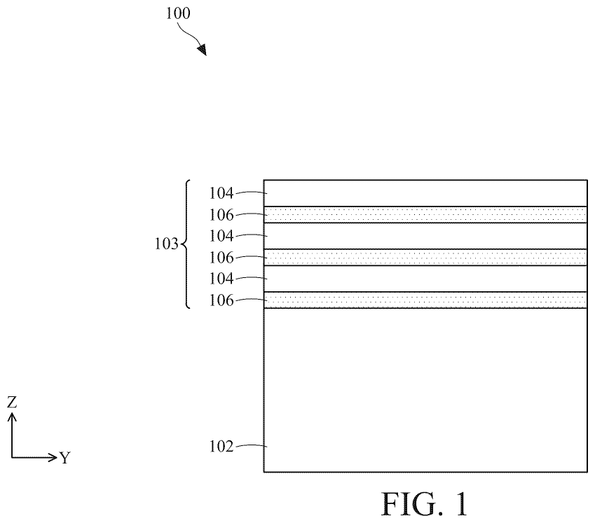

FIGS. 1-14B are cross-sectional views, top views, and perspective views of an integrated circuit 100 fabricated in accordance with some embodiments of the present disclosure. The fabrication process results in a plurality of transistors 101, as will be described in further detail below.

FIG. 1 is a perspective view of the integrated circuit 100 at an intermediate state of processing. The integrated circuit 100 includes a substrate 102. The substrate 102 may be a semiconductor substrate, such as a bulk semiconductor, or the like, which may be doped (e.g., with a p-type or an n-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures. In FIG. 1, Three semiconductor layers 104 and three sacrificial semiconductor layers 106 are illustrated. In some embodiments, the multi-layer stack 103 may include fewer or more layers than are shown in FIG. 1.

In some embodiments, the semiconductor layers 104 may be formed of a first semiconductor material suitable, such as silicon, silicon carbide, or the like, and the sacrificial semiconductor layers 106 may be formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below.

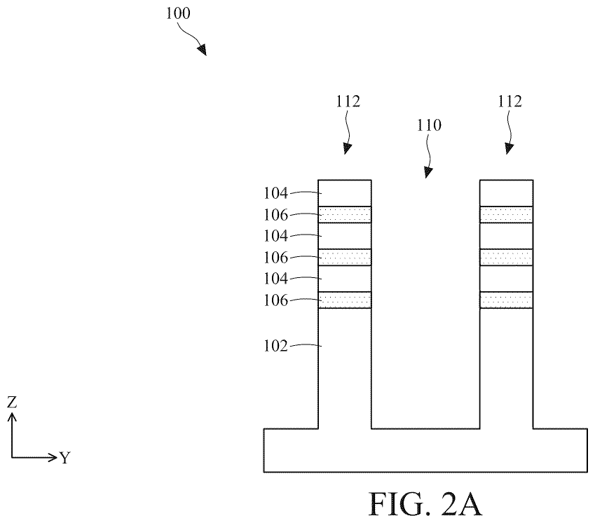

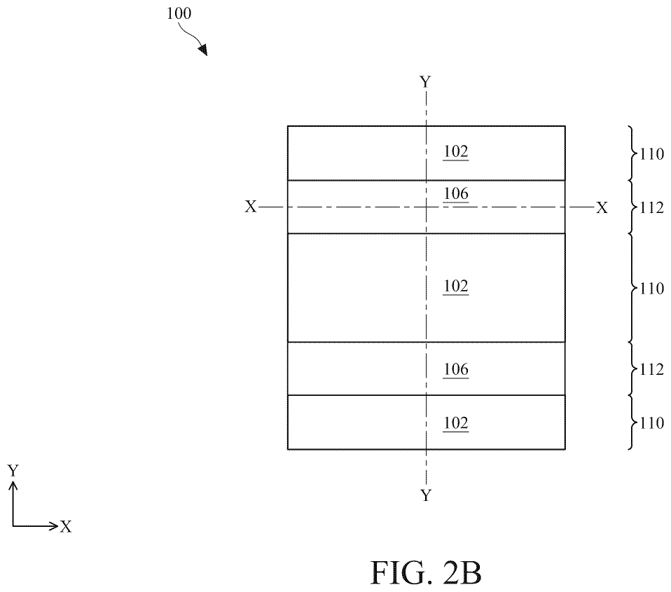

In FIG. 2A, trenches 110 have been formed in the stack 103 and in the substrate 102. Though not shown in FIG. 1, a hard mask layer is first formed and patterned on the stack 103. The trenches 110 can be formed with an anisotropic etching process that etches in the downward direction in the presence of the patterned hard mask. The etching process defines semiconductor fins 112 by forming trenches 110 through the sacrificial semiconductor layers 106, the semiconductor layers 104, and the substrate 102.

FIG. 2B is a top view of the integrated circuit 100 of FIG. 2A, in accordance with some embodiments. The top view of FIG. 2B illustrates the fins 112 extending in the X direction and the trenches 110 between the fins 112. The substrate 102 is visible in the trenches 110. The top-most semiconductor layer 106 is visible atop the fins 112. As set forth previously, in practice, a hard mask layer may be positioned on top of the top-most semiconductor layer 106. FIG. 2B also illustrates cut-lines X and Y. A cross-sectional view along the cut lines Y may be referred to as a “Y-view”. A cross-sectional view along the cut lines X may be referred to as a “X-view”.

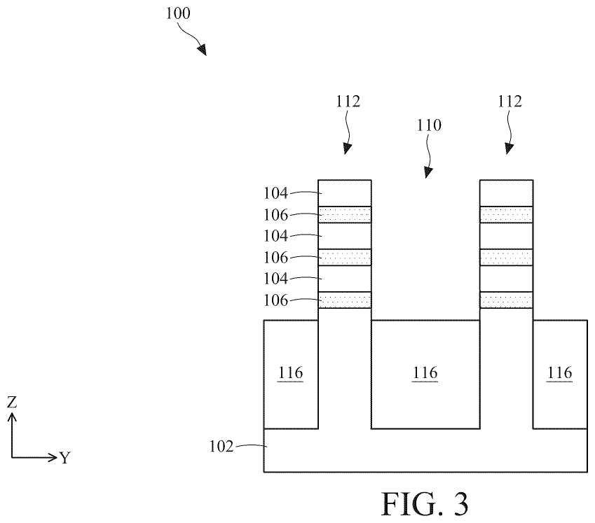

FIG. 3 is a cross-sectional Y-view, in accordance with some embodiments. In FIG. 3, shallow trench isolation regions 116 have been formed by depositing a dielectric material in the trenches 110 between fins 112. The shell dielectric layer may be deposited by chemical vapor deposition (CVD), atomic layer deposition (ALD), physical vapor deposition (PVD), or other suitable deposition processes. In an exemplary embodiment, the dielectric material includes silicon oxide. However, the dielectric material can include SiN, SiCN, SiOC, SiOCN, or other dielectric materials without departing from the scope of the present disclosure. After deposition of the dielectric material, an etch-back process has been performed to recess the top of the shallow trench isolation regions 116 below the lowest sacrificial semiconductor layers 106.

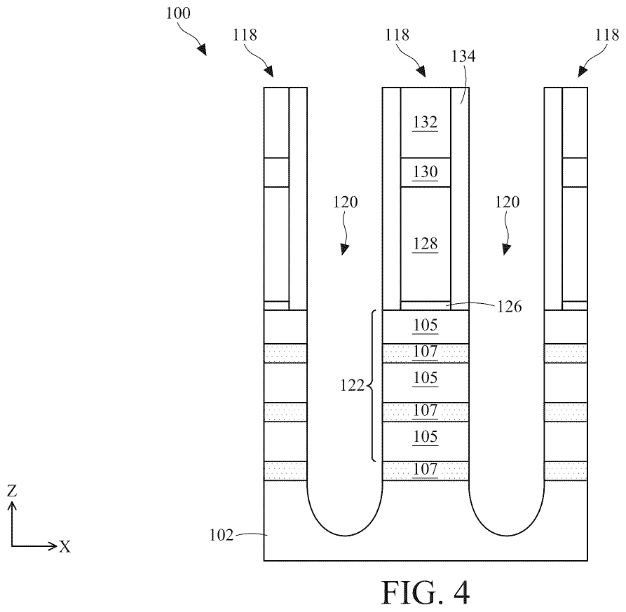

FIG. 4 is an X-view of the integrated circuit 100, in accordance with some embodiments. In FIG. 4, sacrificial gate structures 118 have been formed over the fins 112. The sacrificial gate structures 118 extend in the Y direction, perpendicular to the fins 112. Each sacrificial gate structure 118 crosses multiple fins 112. The sacrificial gate structures 118 are also formed in the trenches 110.

The sacrificial gate structures 118 include a dielectric layer 126. In an exemplary embodiment, the dielectric layer 126 includes silicon oxide. However, alternatively, the dielectric layer 126 can include SiN, SiCN, SiOC, SiOCN, or other dielectric materials without departing from the scope of the present disclosure. In some embodiments, the dielectric layer 126 has a low K dielectric material. The dielectric layer 126 can be deposited by CVD, ALD, or PVD.

The sacrificial gate structures include a sacrificial gate layer 128 on the dielectric layer 126. The sacrificial gate layer 128 can include materials that have a high etch selectivity with respect to the trench isolation regions 116. In an exemplary embodiment, sacrificial gate layer 128 includes polysilicon. However, the sacrificial gate layer 128 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 128 may be deposited by physical vapor deposition (PVD), CVD, sputter deposition, or other techniques for depositing the selected material.

The sacrificial gate structures 118 include a dielectric layer 130 on the sacrificial gate layer 128 and a dielectric layer 132 of the dielectric layer 130. The dielectric layers 130 and 132 may correspond to first and second mask layers. The dielectric layer 130 can include silicon nitride, silicon oxynitride, or other suitable dielectric materials. The dielectric layer 130 can include silicon nitride, silicon oxynitride or other suitable dielectric materials. The dielectric layers 130 and 132 are different materials from each other and can be deposited using CVD, ALD, PVD, or other suitable deposition processes. Other materials and deposition processes can be utilized for the dielectric layers 130 and 132 without departing from the scope of the present disclosure.

Gate spacer layers 134 have been formed on the sidewalls of the layers 126, 128, 130, and 132. The gate spacer layers 134 may also be formed on other exposed surfaces of the integrated circuit. The gate spacer layer 134 can be formed by PVD, CVD, ALD, or other suitable deposition processes. Following formation of the gate spacer layer 134, horizontal portions (e.g., in the X-Y plane) of the gate spacer layer 134 may be removed by an anisotropic etching process, thereby exposing upper surfaces of the fins 112 and the dielectric layer 134. After patterning of the gate spacer layers, vertically thicker portions of the gate spacer layers 134 remain, such as the portion shown in FIG. 4. The gate spacer layers 134 can include one or more of SiO, SiN, SiON, SiCN, SiOCN, SiOC, or other suitable dielectric materials.

After patterning of the gate spacer layers 134, an etching process is performed to form source/drain trenches 120 in the fins 112. One or more etching processes are performed to form the source/drain trenches 120 in the fins 112. Forming the source/drain trenches 120 includes etching through each of the semiconductor layers 104 and sacrificial semiconductor layers 106, and a portion of the substrate 102. Accordingly, the removal operations may include suitable etch operations for removing materials of the semiconductor layers 104, the sacrificial semiconductor layers 106, and the substrate 102. The etching processes can include reactive ion etching (RIE), neutral beam etching (NBE), atomic layer etching (ALE), or the like.

Formation of the source/drain trenches 120 results in formation of stacks of channels 105. In particular, the portions of the semiconductor layers 104 after formation of the source/drain trenches 120 now correspond to channels of a transistor. Formation of the source/drain trenches 120 also results in formation of a plurality of sacrificial semiconductor nanostructures 107 from the sacrificial semiconductor layers 106.

A large number of source/drain trenches 120 are formed in the fins 112. A stack 122 of channels 105 is positioned between each source/drain layer. Each stack 122 of channels 105 corresponds to the stacked channels 105 of a transistor.

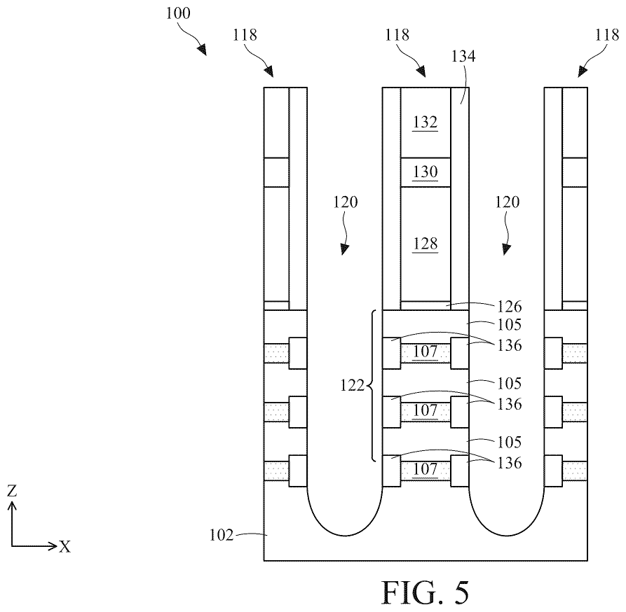

In FIG. 5, inner spacers 136 have been formed. A selective etching process is performed to recess exposed end portions of the sacrificial semiconductor nanostructures 107 without substantially etching the sacrificial semiconductor nanostructures 107. Next, the inner spacers 136 are formed by depositing a dielectric material to fill the recesses between the channels 105 formed by the previous selective etching process of the sacrificial semiconductor nanostructures 107. The inner spacer 136 may be a suitable dielectric material, such as silicon carbon nitride (SiCN), silicon oxycarbonitride (SiOCN), or the like, formed by a suitable deposition method such as physical vapor deposition (PVD), CVD, ALD, or the like. An etching process, such as an anisotropic etching process, is performed to remove portions of the inner spacer 136 disposed outside the recesses in the sacrificial semiconductor nanostructures 107. The remaining portions of the dielectric layer correspond to the inner spacers 136 shown in FIG. 5.

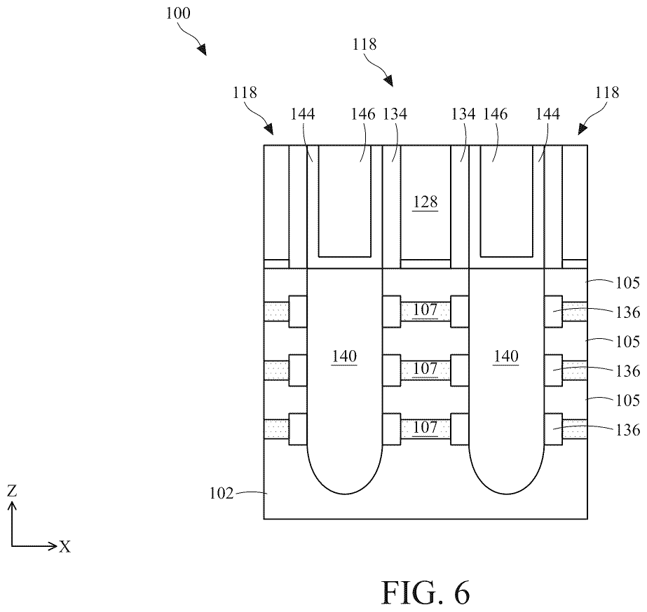

In FIG. 6 source/drain regions 140 have been formed. In the illustrated embodiment, the source/drain regions 140 are epitaxially grown from the channels 105. The source/drain regions 140 are grown on exposed portions of the fins 112 and contact the channels 105. For each stack 122 of channels 105, there are two source/drain regions 140. Some stacks 122 of channels 105 may share a source/drain 140 with a stack 122 of channels 105 that is adjacent in the X direction.

Though not shown, dielectric support elements corresponding to remnants of the gate spacer layers 134 on the trench isolation regions 116 may laterally confine the growth of source/drain regions 140. In some embodiments, the source/drain regions 140 exert stress in the respective channels 105, thereby improving performance. The source/drain regions 140 are formed such that each sacrificial gate structure 118 is disposed between respective neighboring pairs of the source/drain regions 140. In some embodiments, the spacer layer 134 and the inner spacers 136 separate the source/drain regions 140 from the sacrificial gate layer 128 by an appropriate lateral distance (e.g., in the X-axis direction) to prevent electrical bridging to subsequently formed gates of the resulting device.

The source/drain regions 140 may include any acceptable material, such as appropriate for n-type or p-type devices. For n-type devices, the source/drain regions 140 include materials exerting a tensile strain in the channel regions, such as silicon, SiC, SiCP, SiP, or the like, in some embodiments. When p-type devices are formed, the source/drain regions 140 include materials exerting a compressive strain in the channel regions, such as SiGe, SiGeB, Ge, GeSn, or the like, in accordance with certain embodiments. The source/drain regions 140 may have surfaces raised from respective surfaces of the fins and may have facets. Neighboring source/drain regions 140 may merge in some embodiments to form a singular source/drain region 140 over two neighboring fins of the fins 112.

The source/drain regions 140 may be implanted with dopants followed by an annealing process. The source/drain regions 140 may have an impurity concentration of between about 10¹⁹ cm⁻³ and about 10²¹ cm⁻³. N-type and/or p-type impurities for source/drain regions 140 may be any of the impurities previously discussed. In some embodiments, the source/drain regions 140 are in situ doped during growth.

In FIG. 6, a contact etch stop layer (CESL) 144 and an interlayer dielectric (ILD) 146 have been formed above the source/drain regions 140 and between adjacent sacrificial gate structures. The CESL layer 144 can include a thin dielectric layer can formally deposited on exposed surfaces of the source/drain regions 140 and on other exposed surfaces. The CESL layer 144 can include SiN, SiC, SiOC, SiOCN, SiON, or other suitable dielectric materials. The CESL 144 can be deposited by CVD, ALD, PVD, or other suitable deposition processes.

The dielectric layer 146 covers the CESL 144. The dielectric layer 146 can include SiO, SiON, SiN, SiC, SiOC, SiOCN, SiON, or other suitable dielectric materials. The dielectric layer 146 can be deposited by CVD, ALD, PVD, or other suitable deposition processes.

In FIG. 6, a CMP process has been performed to reduce the height of the sacrificial gate structures 118. The result of the CMP process is that the dielectric layers 130 and 132 are entirely removed. The heights of the sacrificial gate layer 128, the gate spacer layers 134, the CESL layer 144, and the dielectric layer 146 have been reduced and the top surfaces have been planarized.

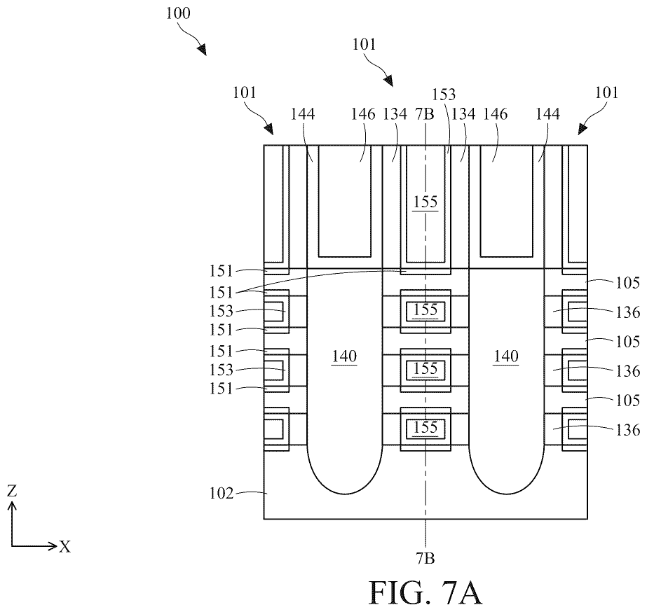

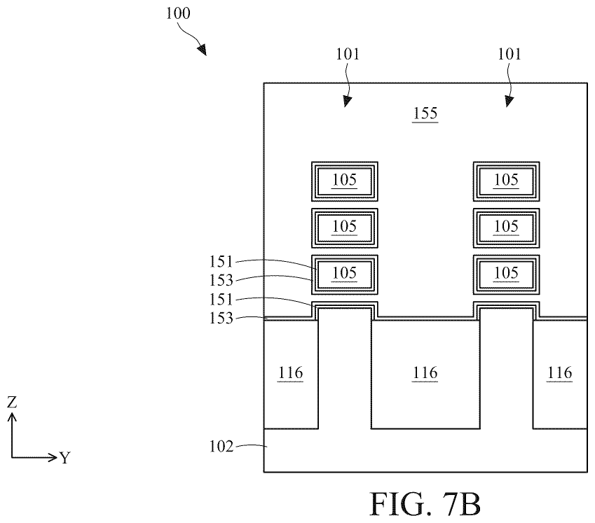

FIG. 7A is an X-view of the integrated circuit 100, in accordance with some embodiments. In FIG. 7A, the sacrificial gate structures 118 have been removed from between the gate spacer layers 134. In particular, the dielectric layer 126 and the sacrificial gate layer 128 have been entirely removed from between the gate spacer layers 134.

In some embodiments, the sacrificial gate layer 128 is removed by an anisotropic dry etch process. For example, the etching process may include a dry etch process using reaction gases that selectively etch the sacrificial gate layer 128 without etching the spacer layer 134. The dielectric layer 126, when present, may be used as an etch stop layer when the sacrificial gate layer 128 is etched. The dielectric layer 126 may then be removed after the removal of the sacrificial gate layer 128.

Removal of the sacrificial gate layer 128 and the dielectric layer 126 results in the formation of a void between the gate spacer layers 134 above the channels 105. As will be set forth in more detail below, an upper portion of a gate metal or gate electrode will be formed in the void. Accordingly, the sacrificial gate layer 128 is sacrificial in the sense that the upper portion of the gate metal will eventually be formed in its place.

In FIG. 7A, channels 105 are released by removal of the sacrificial semiconductor nanostructures 107. The sacrificial semiconductor nanostructures 107 can be removed by a selective etching process using an etchant that is selective to the material of the sacrificial semiconductor nanostructures 107, such that the sacrificial semiconductor nanostructures 107 are removed without substantially etching the channels 105. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. In some embodiments, the sacrificial semiconductor nanostructures 107 are removed and the channels 105 are patterned to form channel regions of both PFETs and NFETs. Removal of the sacrificial semiconductor nanostructures 107 results in the formation of voids between the channels 105.

After release of the channels 105, an interfacial gate dielectric layer 151 has been deposited. The interfacial gate dielectric layer 151 is deposited on all exposed surfaces of the channels 105. The interfacial gate dielectric layer 151 is wrapped around the channels 105. The interfacial gate dielectric layer 151 can include a dielectric material such as silicon oxide, silicon nitride, or other suitable dielectric materials. The interfacial gate dielectric layer 151 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 151 can be formed by a thermal oxidation process, a chemical vapor deposition (CVD) process, or an atomic layer deposition (ALD) process. The interfacial gate dielectric layer 151 can have a thickness between 0.5 nm and 2 nm. Other materials, deposition processes, and thicknesses can be utilized for the interfacial gate dielectric layer 151 without departing from the scope of the present disclosure.

A high-K dielectric layer 153 has been deposited. The high-K dielectric layer 153 is deposited in a conformal deposition process. The conformal deposition process deposits the high-K dielectric layer 153 on the interfacial gate dielectric layer 151, on the hard mask structure 109, on the substrate 102, on the trench isolation regions 116, and on the gate spacer layers 134. The high-K gate dielectric layer 153 is wrapped around the channels 105. The high-K gate dielectric layer 153 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K dielectric layer 153 may be formed by CVD, ALD, or any suitable method. Other thicknesses, deposition processes, and materials can be utilized for the high-K dielectric layer 153 without departing from the scope of the present disclosure.

A gate metal 155 has been deposited. The gate metal 155 is deposited on all exposed surfaces of the high-K dielectric layer 153. The gate metal 155 is wrapped around the channels 105. Although the gate metal 155 is shown as a single layer in FIG. 7, in practice, the gate metal 155 can include one or more conductive liner layers, work function layers, and gate fill layers that collectively make up the gate metal. The gate metal can include one or more of Ti, TiN, Ta, TaN, Al, Cu, Co, Ru, W, Au, or other suitable conductive materials. The gate metal 155 can be deposited by PVD, ALD, or CVD. Other configurations, materials, and deposition processes can be utilized for the gate metal 155 without departing from the scope of the present disclosure. The gate metal 155 acts as a gate electrode surrounding the channels 105.

At the stage of processing shown in FIGS. 7A and 7B, the transistors 101 are substantially complete. Each transistor 101 includes a stack 122 of channels 105 extending between the source/drain regions 140 and acting as stacked channels of the transistor 101. As set forth in more detail below, source/drain contacts and cut metal gate structures have not yet been formed.

FIG. 7B is a Y-view of the integrated circuit 100 at the stage of processing of FIG. 7A, taken along cut lines 7B, in accordance with some embodiments. FIG. 7B illustrates that of the current stage of processing there are no breaks in the gate metal 155 between transistors 101 adjacent to each other in the Y direction. Accordingly, the gate electrodes of adjacent transistors 101 in the Y direction are shorted together.

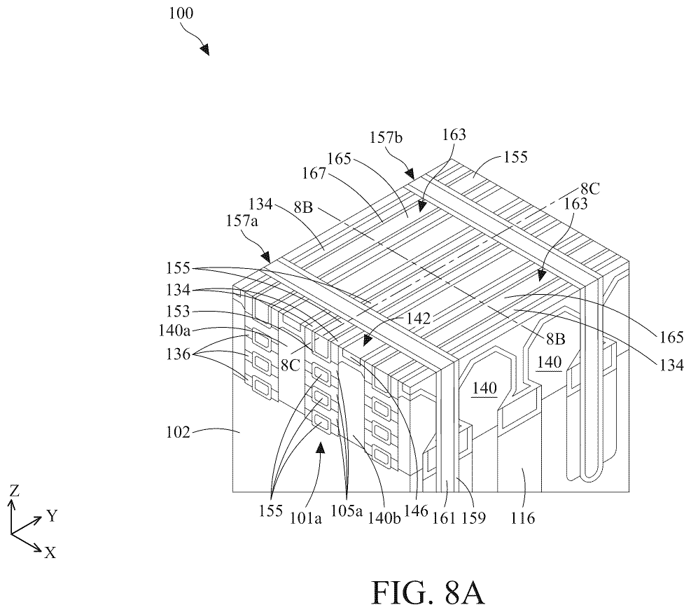

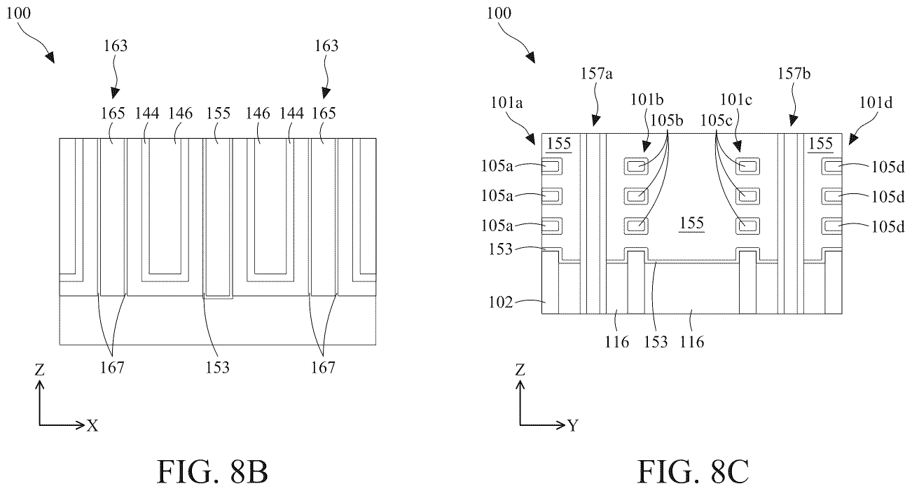

FIG. 8A is a perspective view of the integrated circuit 100, in accordance with some embodiments. In FIG. 8A, gate isolation structures 157a and 157b have been formed. In some instances herein, reference numbers may include a suffix “a”, “b”, “c”, or “d”. The gate isolation structures 157a and 157b are one example of this. Throughout the specification, the suffix “a”, “b”, “c”, or “d” may be omitted when reference is not particular to a specific structure. For example, when description applies to both the gate isolation structures 157a and 157b, the description may simply refer to the gate isolation structures 157 without the suffix “a” or “b”. This applies to other reference numbers with suffixes. The gate isolation structures 157 may also be termed “cut metal gate” (CMG) structures. The gate isolation structures 157 electrically isolate the gate electrodes of transistors 101 adjacent to each other in the Y direction.

The gate isolation structures 157 include a dielectric layer 159. The dielectric layer 159 corresponds to a dielectric liner layer and can include SiO, SiON, SiN, SiC, SiOC, SiOCN, SiON, or other suitable dielectric materials. The dielectric layer 159 can be deposited by CVD, ALD, PVD, or other suitable deposition processes.

The gate isolation structures include a dielectric layer 161. The dielectric layer 161 fills the gaps between the adjacent portions of the dielectric liner layer 159. The dielectric layer 161 can include SiO, SiON, SiN, SiC, SiOC, SiOCN, SiON, or other suitable dielectric materials. The dielectric layer 161 can be deposited by CVD, ALD, PVD, or other suitable deposition processes. In an exemplary embodiment, the dielectric layer 159 includes silicon nitride and the dielectric layer 161 include silicon oxide.

The gate isolation structures 157 can be formed by forming trenches in the integrated circuit 100 in locations at which the gate isolation structures 157 are to be formed. The trenches extend into the trench isolation regions 116 and etch entirely through the gate metal 155 so that the gate metals 155 of transistors adjacent in the Y direction are electrically isolated from each other. After formation of the trenches, the dielectric layers 159 and 161 can be formed as described above, resulting in formation of the gate isolation structures 157.

In FIG. 8A, a transistor 101a is indicated, in accordance with some embodiments. The transistor 101a includes a plurality of channels 105a each extending in the X direction between a source/drain region 140a and a source/drain region 140b. The gate metal 155 wraps around the channels 105a. In FIG. 8A, the interfacial dielectric layer 151 is not shown (though still present). FIG. 8A and subsequent figures illustrate only the high-K dielectric layer 153. The inner spacers 136 electrically isolate the gate metal 155 from the source/drain regions 140. The high-K dielectric layer 153 is a gate dielectric layer.

In FIG. 8A, continuous poly on diffusion edge (CPODE) structures 163 have been formed in place of the gate metal 155 at some locations between adjacent gate isolation structures 157a and 157b. The CPODE structures 163 include a polysilicon layer 165 and a dielectric layer 167. The dielectric layer 167 is a dielectric liner layer positioned on sidewalls of the gate spacer layers 134. The dielectric layer 167 can include SiO, SiON, SiN, SiC, SiOC, SiOCN, SiON, or other suitable dielectric materials. The dielectric layer 159 can be deposited by CVD, ALD, PVD, or other suitable deposition processes. A CMP process has been performed to planarize the top surface of the integrated circuit 100.

FIG. 8A illustrates cut lines 8B extending in the X direction. FIG. 8A also illustrates cut lines 8C extending in the Y direction. In subsequent figures, X-view figures are taken along cut lines 8B. Y-view figures are taken along cut lines 8C.

FIG. 8B is a cross-sectional X-view of the integrated circuit 100 of FIG. 8A, in accordance with some embodiments. FIG. 8B illustrates the CPODE structures 163, the CESL layer 144 and the interlevel dielectric layer 146, and the gate electrode 155, in accordance with some embodiments.

FIG. 8C is a cross-sectional Y-view of the integrated circuit 100 of FIG. 8A, in accordance with some embodiments. FIG. 8C illustrates four stacks of channels 105a-d of four transistors 101a-d. The transistor 101a includes the channels 105a surrounded by the gate metal 105 on the left side of the gate isolation structure 157a. The transistor 101b includes the channels 101b surround by the gate metal 155 on the right side of the gate isolation structure 157a. The transistor 101c includes the channels 105c surrounded by the gate metal 155 on the left side of the gate isolation structure 157b. The transistor 101d includes the channels 105d surrounded by the gate metal 155 on the right side of the gate isolation structure 157b.

FIG. 8C illustrates that the gate metals 155 of the transistors 101b and 101c are shorted. The gate isolation structure 157a electrically isolates the gate metal 155 of the transistor 101a from the gate metal 155 of the transistors 101b and 101c. The gate isolation structure 157b electrically isolates the gate metal 155 of the transistor 101d from the gate metal 155 of the transistors 101b and 101c.

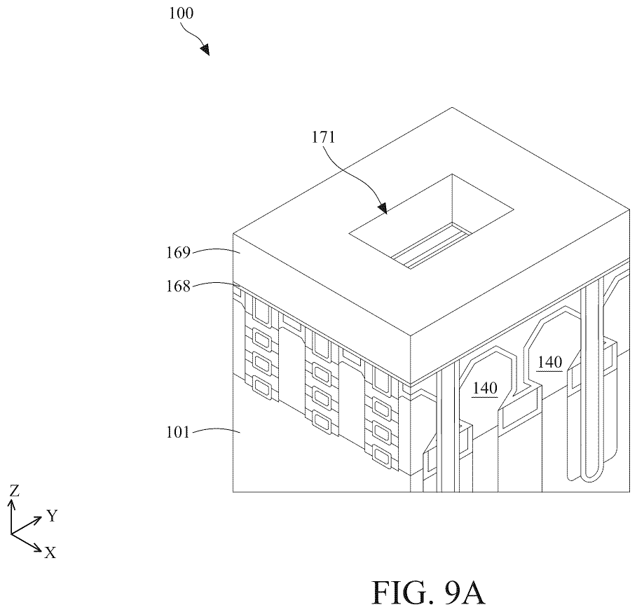

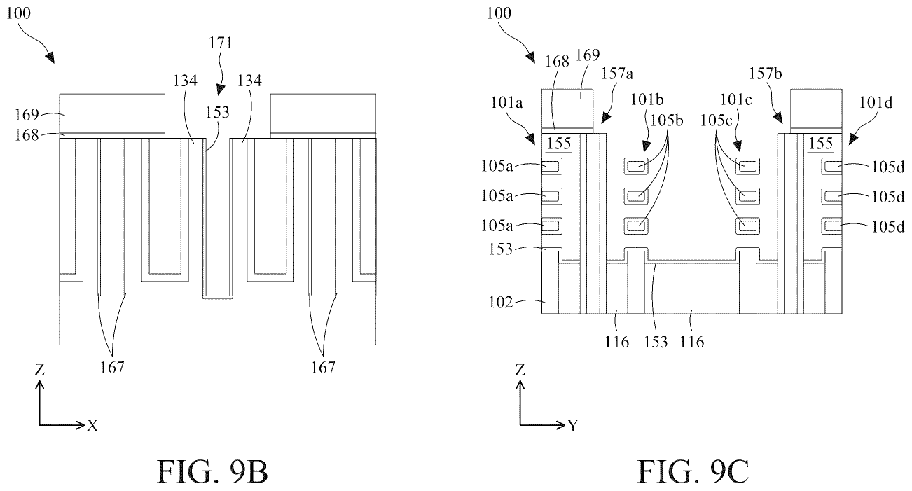

FIG. 9A is a perspective view of the integrated circuit 100, in accordance with some embodiments In FIG. 9A, a dielectric layer 168 has been deposited on a top surface of the integrated circuit 100 is shown in FIG. 8A, in accordance with some embodiments. The dielectric layer 168 corresponds to a hard mask layer. The dielectric layer 168 can include SiO, SiON, SiN, SiC, SiOC, SiOCN, SiON, or other suitable dielectric materials. The dielectric layer 168 can be deposited by CVD, ALD, PVD, or other suitable deposition processes.

In FIG. 9A, a dielectric layer 169 has been formed on the dielectric layer 168. The dielectric layer 169 corresponds to an interlevel dielectric layer. The dielectric layer 169 can include SiO, SiON, SiN, SiC, SiOC, SiOCN, SiON, or other suitable dielectric materials. The dielectric layer 169 can be deposited by CVD, ALD, PVD, or other suitable deposition processes.

In FIG. 9A, a photolithography process and a corresponding etching process have been performed to open a trench 171 in the dielectric layers 168 and 169. Though not apparent in the view of FIG. 9A, the trench 171 exposes the gate metal 155 between the gate isolation structures 157a and 157b. In particular, the trench 171 exposes the gate metal 155 surrounding the channels 105b and 105c.

In FIG. 9A, though not apparent, an etching process has been performed to remove the gate metal 155 at the exposed locations. The etching process selectively etches the material of the gate metal 155 with respect to the material of exposed dielectric structures.

FIG. 9B is an X-view of the integrated circuit 100 at the stage of processing of FIG. 9A, in accordance with some embodiments. FIG. 9C is a Y-view of the integrated circuit 100 at the stage of processing of FIG. 9A, in accordance with some embodiments. FIGS. 9B and 9C illustrates that the gate metal 155 has been removed at locations exposed by the trench 171. The high-K dielectric layer 153 is still present on the gate spacer layers 134 and the channels 101b and 101c. The gate metal 155 has been removed between the gate isolation structures 157a and 157b. The gate metal 155 still surrounds the channels 105a of the transistor 101a and the channels 105d of the transistor 101d.

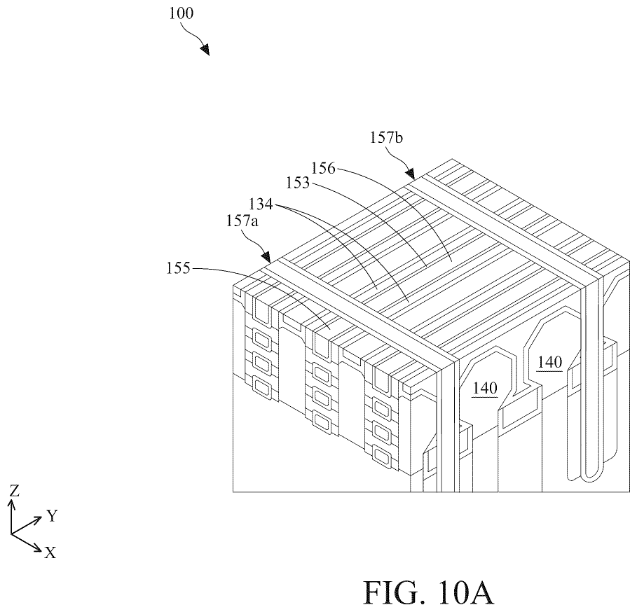

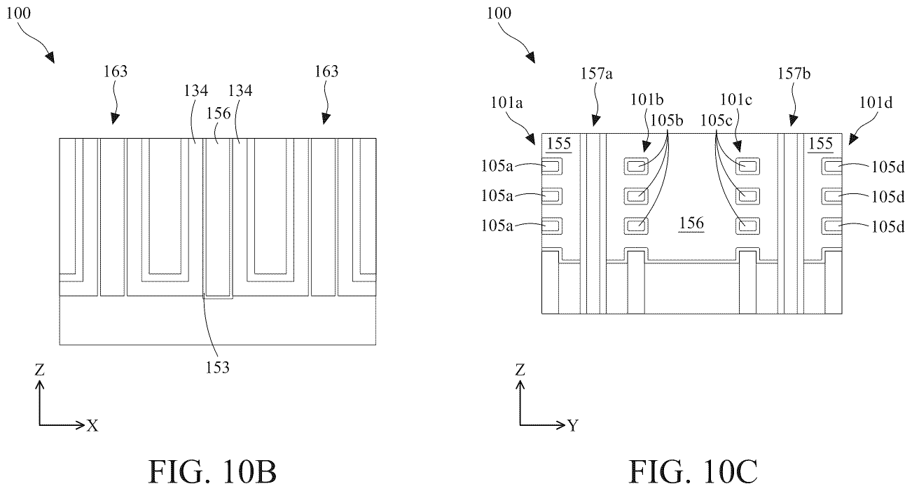

FIG. 10A is a perspective view of the integrated circuit 100, in accordance with some embodiments. In FIG. 10A, a dummy gate metal 156 has been deposited in place of the gate metal 155 that was removed. The dummy gate metal 156 is a different material than the gate metal 155. In some embodiments, the dummy gate metal 156 has a lower resistance than the gate metal 155. The dummy gate metal 156 can be deposited by PVD, ALD, CVD, or other suitable deposition processes. The dummy gate metal can include tungsten, titanium, aluminum, tantalum, or other suitable conductive materials. In one example, the gate metal 155 includes titanium nitride of relatively high resistivity and the dummy gate metal 156 includes tungsten of significantly lower resistivity than the titanium nitride gate metal. Other combinations of metals can be utilized for the gate metal 155 and the dummy gate metal 156 without departing from the scope of the present disclosure. A lower resistance metal can be utilized for the dummy gate metal 156 based, in part, on the fact that there does not need to be consideration of using a work function metal as the transistors 101b and 101c will be dummy transistors that do not function. The dummy gate metal 156 may be termed a filler metal, a second gate metal, or a substitute gate metal. The dummy transistors 101b and 101c may be termed dummy structures that have the form of transistors but that do not function.

FIG. 10B is an X-view of the integrated circuit 100 of FIG. 10A, in accordance with some embodiments. FIG. 10C is a Y-view of the integrated circuit 100 of FIG. 10A, in accordance with some embodiments. FIG. 10B illustrates the dummy gate metal 156 on the high-K dielectric 153 between the gate spacer layers 134. FIG. 10C illustrates the dummy gate metal 156 wrapped around the channels 105b and 105c between the gate isolation structures 157a and 157b.

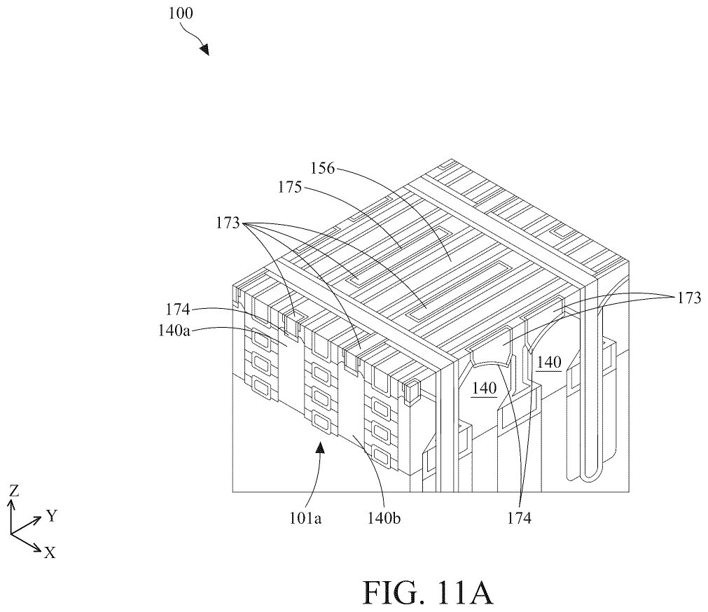

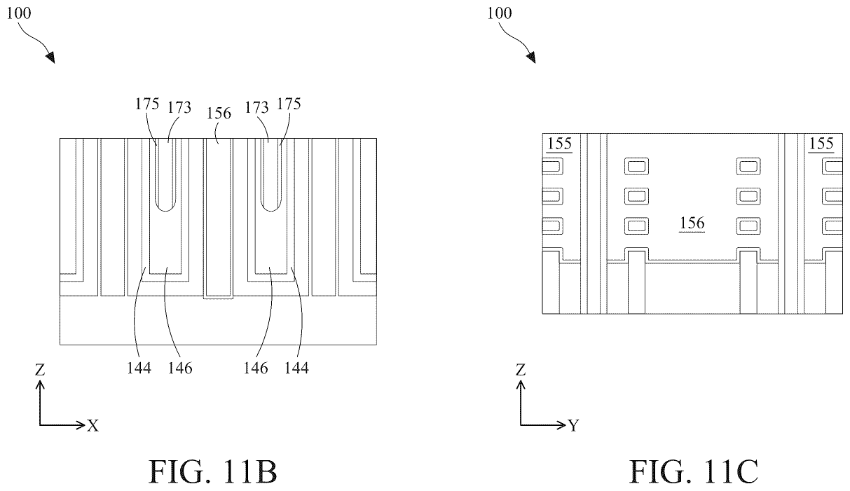

FIG. 11A is a perspective view of the integrated circuit 100, in accordance with some embodiments. In FIG. 11A, source/drain contacts 173 have been formed. Prior to formation of the source/drain contacts 173, a photolithography process and corresponding etching process have been performed. The photolithography and etching process forms trenches that expose the source/drain regions 140 at selected locations.

After formation of the trenches for the source/drain contacts 173, a silicide 174 is formed on the source/drain regions 140. The silicide 174 can be formed after depositing the materials of the source/drain contacts 173. In particular, after the materials of the source/drain contacts 173 are deposited, a thermal annealing process can be performed. The thermal annealing process results in formation of a silicide 174 at the interface between the semiconductor materials of the source/drain regions 140 and the metal of the source/drain contacts 173.

In some embodiments, the source/drain contacts 173 can include tungsten, aluminum, titanium, titanium nitride, tantalum, tantalum nitride, molybdenum ruthenium, selenium, or other suitable conductive materials. The source/drain contacts 173 can be formed by PVD, ALD, CVD, or other suitable deposition processes.

In some embodiments, a dielectric liner layer 175 is formed in the trenches prior to deposition of the material for the source/drain contacts 173. The dielectric layer 175 can include SiO, SiON, SiN, SiC, SiOC, SiOCN, SiON, or other suitable dielectric materials. The dielectric layer 175 can be deposited by CVD, ALD, PVD, or other suitable deposition processes.

FIG. 11B is an X-view of the integrated circuit 100 of FIG. 11A, in accordance with some embodiments. FIG. 11C is a Y-view of the integrated circuit 100 of FIG. 11A, in accordance with some embodiments. FIG. 11B illustrates the source/drain contacts 142 extending into the interlevel dielectric layer 146. The source/drain contacts 173 are not apparent in FIG. 11C.

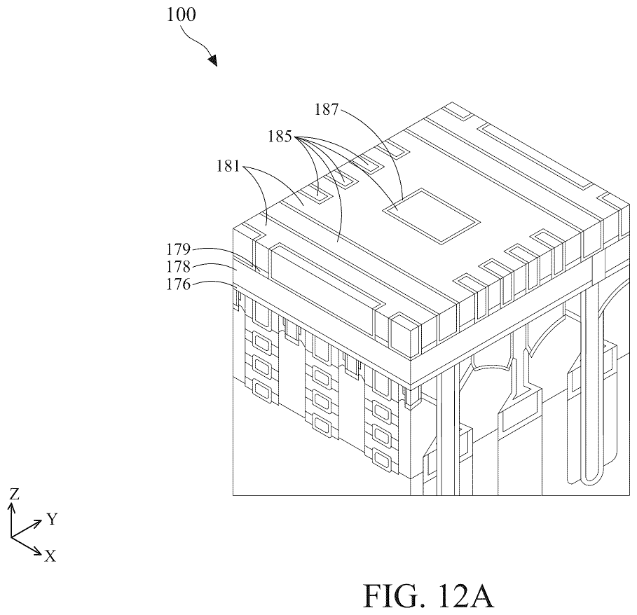

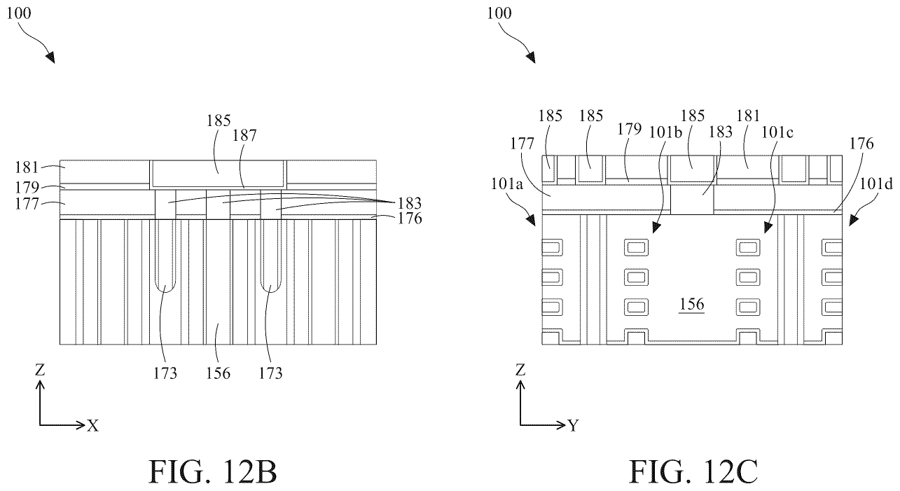

FIG. 12A is a perspective view of the integrated circuit 100, in accordance with some embodiments. In FIG. 12A, a dielectric layer 176 has been deposited on a top surface of the integrated circuit 100 as shown in FIG. 11A, in accordance with some embodiments. The dielectric layer 176 corresponds to a hard mask layer. The dielectric layer 176 can include SiO, SiON, SiN, SiC, SiOC, SiOCN, SiON, or other suitable dielectric materials. The dielectric layer 176 can be deposited by CVD, ALD, PVD, or other suitable deposition processes.

In FIG. 12A, a dielectric layer 177 has been formed on the dielectric layer 176. The dielectric layer 177 corresponds to an interlevel dielectric layer. The dielectric layer 177 can include SiO, SiON, SiN, SiC, SiOC, SiOCN, SiON, or other suitable dielectric materials. The dielectric layer 177 can be deposited by CVD, ALD, PVD, or other suitable deposition processes.

Though not apparent in view of FIG. 12A, a photolithography process and a corresponding etching process have been performed to open trenches in the dielectric layers 176 and 177. The trenches expose the source/drain contacts 173 and the dummy gate metal 156 at selected locations for conductive vias 183. After formation of the trenches for the conductive vias 183, the conductive vias 183 are formed by depositing a conductive material in the trenches. The conductive material can include tungsten, titanium, aluminum, titanium nitride, tantalum nitride, tantalum, ruthenium, selenium, or other suitable conductive materials. The conductive vias 183 can be formed by PVD, ALD, CVD, or other suitable deposition processes. A CMP process is performed after formation of the conductive vias 183 to remove excess metal material from the top surface of the dielectric layer 177.

FIG. 12B is an X-view of the integrated circuit 100 of FIG. 12A, in accordance with some embodiments. FIG. 12C is a Y-view of the integrated circuit 100 of FIG. 12A, in accordance with some embodiments. FIG. 12B illustrates the conductive vias 183 contacting the source/drain contacts 173 and the dummy gate metal 156. FIG. 12C illustrates a conductive via contacting the dummy gate metal 156.

Returning to FIG. 12A, a dielectric layer 179 has been deposited on the dielectric layer 177 after formation of the conductive vias 183. The dielectric layer 179 corresponds to a hard mask layer. The dielectric layer 179 can include SiO, SiON, SiN, SiC, SiOC, SiOCN, SiON, or other suitable dielectric materials. The dielectric layer 176 can be deposited by CVD, ALD, PVD, or other suitable deposition processes.

In FIG. 12A, a dielectric layer 181 has been formed on the dielectric layer 179. The dielectric layer 181 corresponds to an interlevel dielectric layer. The dielectric layer 181 can include SiO, SiON, SiN, SiC, SiOC, SiOCN, SiON, or other suitable dielectric materials. The dielectric layer 181 can be deposited by CVD, ALD, PVD, or other suitable deposition processes.

After deposition of the dielectric layers 179 and 181, a photolithography process and a corresponding etching process have been performed to open trenches in the dielectric layers 179 and 181 for formation of metal lines 185 in the front side metal 0 layer. The trenches expose the conductive vias 183 at selected locations. After formation of the trenches for the metal lines 185, the metal lines 185 are formed by depositing a conductive material in the trenches. The conductive material can include tungsten, titanium, aluminum, titanium nitride, tantalum nitride, tantalum, ruthenium, selenium, or other suitable conductive materials. The metal lines 185 can be formed by PVD, ALD, CVD, or other suitable deposition processes.

In some embodiments, a conductive liner layer 187 is formed in the trenches prior to formation of the metal lines 185. The conductive liner layer 187 can include titanium nitride, tantalum nitride or other suitable conductive materials. The conductive liner layer 187 can be formed by PVD, ALD, CVD, or other suitable deposition processes.

Returning to FIGS. 12B and 12C, FIG. 12B illustrates a metal line 185 in contact with three conductive vias 183 that respectably contact source/drain contacts and the dummy gate metal 156. FIG. 12C illustrates a metal line 185 in contact with a conductive via 183 in contact with the dummy gate metal 156. FIG. 12C also illustrates a plurality of other metal lines 185 formed in the interlevel dielectric layer 181.

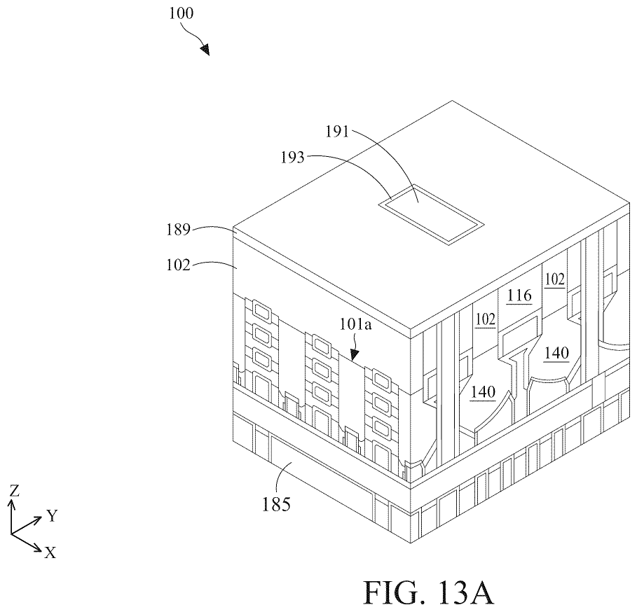

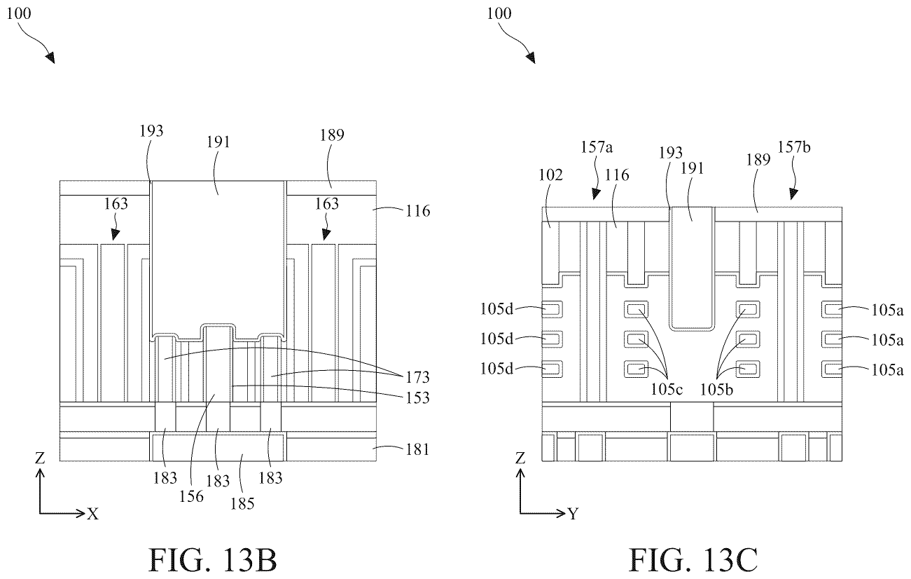

FIG. 13A is a perspective view of the integrated circuit 100, in accordance with some embodiments. In FIG. 13A, the integrated circuit 100 has been flipped such that the substrate 102 is that the top and the metal lines 185 are at the bottom of the figure. The integrated circuit 100 has been flipped to facilitate formation of a feedthrough via 191 that electrically connects to the dummy gate metal 156 and adjacent source/drain contacts 173. The feedthrough via 191 may also be described as a conductive backside via.

In FIG. 13A, a dielectric layer 189 has been formed on the backside of the integrated circuit 100. In particular, the dielectric layer 189 has been formed on the semiconductor substrate 102 and on the trench isolation regions 116. In this case, the semiconductor substrate 102 and the trench isolation regions 116 may be collectively considered as a substrate. The dielectric layer 189 corresponds to a hard mask layer. The dielectric layer 189 can include SiO, SiON, SiN, SIC, SiOC, SiOCN, SiON, or other suitable dielectric materials. The dielectric layer 189 can be deposited by CVD, ALD, PVD, or other suitable deposition processes.

In FIG. 13A, a photolithography process and the corresponding etching process has been performed to form a trench through the dielectric layer 189 and the substrate to expose the dummy gate metal 156 and selected source/drain contacts 173. After formation of the trench, a conductive liner layer 193 is formed in the trench. The conductive liner layer 193 can include titanium nitride, tantalum nitride, or other suitable conductive materials. The conductive liner layer 193 can be formed by PVD, ALD, CVD, or other suitable deposition processes.

After formation of the conductive liner layer 193, the feedthrough via 191 is formed by depositing a conductive material in the trench on the conductive liner layer 193. The feedthrough via 191 can include tungsten, aluminum, titanium, titanium nitride, tantalum nitride, ruthenium, selenium, or other suitable conductive materials. The feedthrough via 191 can be formed by PVD, ALD, CVD, or other suitable deposition processes. A CMP process is performed after formation of the feedthrough via 191 to remove excess conductive material from the top surface of the dielectric layer 189.

FIG. 13B is an X-view of the integrated circuit 100 of FIG. 13A, in accordance with some embodiments. FIG. 13C is a Y-view of the integrated circuit 100 of FIG. 13A, in accordance with some embodiments. FIG. 13B illustrates the feedthrough via 191 contacting the source/drain contacts 173 and the dummy gate metal 156. FIG. 13C illustrates the feedthrough via 191 contacting the dummy gate metal 156. FIG. 13C also illustrates that the trench for the feature via 191 extends into the dummy gate metal 156 beyond at least one of the channels 105b/c.

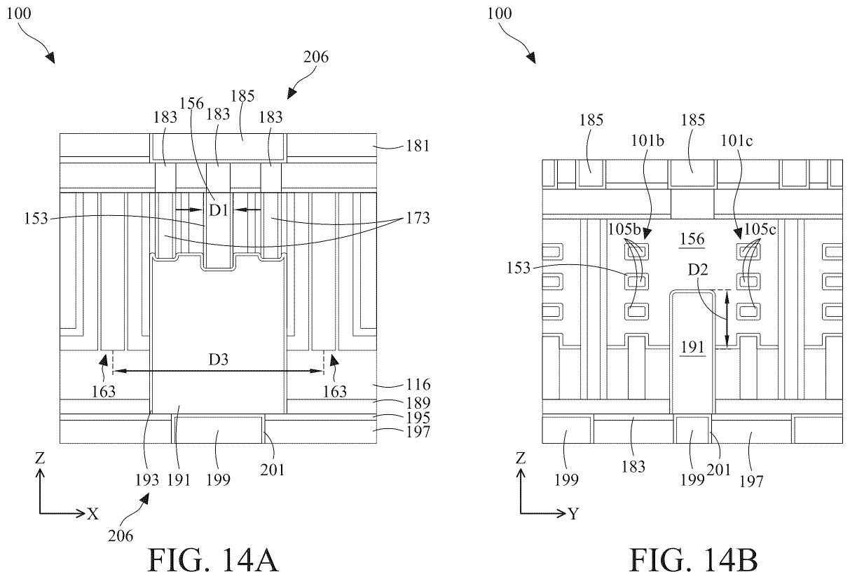

FIG. 14A is an X-view of the integrated circuit 100, in accordance with some embodiments. FIG. 14B is a Y-view of the integrated circuit 100 at the stage of processing of FIG. 14A, in accordance with some embodiments. Although the orientation of FIGS. 14A and 14B (as well as in subsequent figures) are returned so that the backside of the integrated circuit 100 is at the bottom of each figure, the backside processes described are performed with the orientation flipped as described in relation to FIGS. 13A-13C.

In FIGS. 14A and 14B, a dielectric layer 195 has been formed on the backside of the integrated circuit 100. In particular, the dielectric layer 195 has been formed on the dielectric layer 189. The dielectric layer 195 corresponds to a hard mask layer. The dielectric layer 195 can include SiO, SiON, SiN, SiC, SiOC, SiOCN, SiON, or other suitable dielectric materials. The dielectric layer 195 can be deposited by CVD, ALD, PVD, or other suitable deposition processes.

A dielectric layer 197 has been formed on the backside of the integrated circuit 100. In particular, the dielectric layer 197 has been formed on the dielectric layer 195. The dielectric layer 197 corresponds to a backside interlevel dielectric layer. The dielectric layer 197 can include SiO, SiON, SiN, SiC, SiOC, SiOCN, SiON, or other suitable dielectric materials. The dielectric layer 197 can be deposited by CVD, ALD, PVD, or other suitable deposition processes.

In FIGS. 14A and 14B, a photolithography process and a corresponding etching process have been performed to form trenches through the dielectric layers 195 and 197 to expose the feedthrough via 191 and that other selected locations. After formation of the trenches, a conductive liner layer 201 is formed in the trenches. The conductive liner layer 201 can include titanium nitride, tantalum nitride, or other suitable conductive materials. The conductive liner layer 201 can be formed by PVD, ALD, CVD, or other suitable deposition processes.

After formation of the conductive liner layer 201, metal lines 199 of backside metal BO are formed by depositing a conductive material in the trenches on the conductive liner layer 201. The metal lines 199 can include tungsten, aluminum, titanium, titanium nitride, tantalum nitride, ruthenium, selenium, or other suitable conductive materials. The metal lines 199 can be formed by PVD, ALD, CVD, or other suitable deposition processes. A CMP process is performed after formation of the feedthrough via 199 to remove excess conductive material from the top surface of the dielectric layer 197.

At the stage of processing shown in FIGS. 14A and 14B, front side metal lines 185 and backside metal lines 199 have been formed. At least one of the front side metal lines 185 is electrically connected to at least one of the backside metal lines 199 by the feedthrough via 191, the dummy gate metal 156, and the conductive via 183. The feedthrough via 191, the gate structure including the dummy gate metal 156, the source/drain contacts 173, the conductive vias 183, the front side metal line 185, and the backside metal line 199 collectively correspond to a feedthrough via structure 206. The feedthrough via structure 206 is bound by the low CPODE structures 163 in the X direction for low area penalty. The feedthrough via structure 206 is bound by the gate isolation structures 157a/b for larger length in the Y direction, resulting in low electrical resistance.

In some embodiments, the dummy gate metal 156 may also be termed a second gate metal. The second gate metal 156 is different from the gate metal 155 of other logic transistors 101, such as the logic transistors 101a and 101d. The second gate metal 156 can include tungsten or other low resistance material such as ruthenium, molybdenum, copper, iridium, or other suitable metals. Although not shown in FIGS. 14A and 14B, the second gate metal 156 can also include a conductive liner layer such as titanium nitride, tantalum nitride, or other suitable conductive liner materials.

In some embodiments, the high-K dielectric layer 153, corresponding to a gate dielectric layer may be present between the dummy gate metal 156 and the channels 105b/c, as well as between the dummy gate metal 156 and the gate spacer layers 134. The high-K dielectric layer 153 may have a thickness between zero point one nanometers and 5 nm and can include Si, O, C, N, Hf, or other suitable dielectric materials.

In some embodiments, the dummy gate metal 156 has a dimension D1 in the X direction. D1 can be between 8 nm and 54 nm, though other dimensions can be utilized without departing from the scope of the present disclosure. In some embodiments, the dummy gate metal 156 has the same profile or dimensions as the gate metal 155.

In some embodiments, feedthrough via 191 protrudes into the dummy gate metal 156 a dimension D2 corresponding to a distance between the bottom of the dummy gate metal 156 and the top of the feedthrough via 191 and the orientation shown in FIG. 14B. The dimension D2 can be between 0.1 nm and 70 nm, though other dimensions can be utilized without departing from the scope of the present disclosure. The dimension D2 can be based, in part, on the rate at which the etching process to form the trench for the feedthrough via 191 etches the dummy gate metal 156.

In some embodiments, a dimension D3 corresponds to a pitch of between adjacent CPODE structures 163. The dimension D3 may correspond to twice the contact poly pitch (CPP). The dimension D3 is greater than or equal to twice the width of the of the feedthrough via 191 in the X direction.

As described previously, the dummy gate metal 156 is formed between the gate all around transistors 101a and 101d. The dummy gate metal 156 surrounds channels 105b and 105c that have substantially the same dimensions and characteristics as the channels 105a and 105d of the transistors 101a and 101d. However, the channels 105b and 105c are no longer part of functioning transistors because the source/drain contacts 173 are merged or shorted with the dummy gate metal 156.

In some embodiments, the transistors 101b and 101c correspond to dummy transistors that have the structure of a transistor, the do not function as a transistor. The channels 105b and 105c are dummy channels. The source/drain contacts 173 are dummy source/drain contacts 173. In some embodiments, the dummy gate metal 156 may be termed a substitute gate metal or a second gate metal.

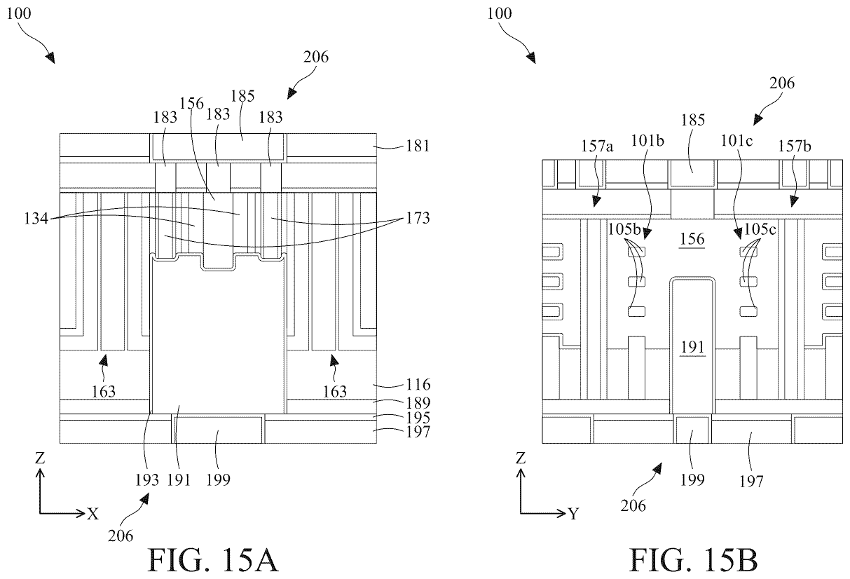

FIG. 15A is an X-view of the integrated circuit 100, in accordance with some embodiments. FIG. 15B is a Y-view of the integrated circuit 100 at the stage of processing of FIG. 15A, in accordance with some embodiments. The integrated circuit 100 of FIGS. 15A and 15B is substantially similar to the integrated circuit 100 of FIGS. 14A and 14B. One difference is that in FIGS. 15A and 15B, the high-K dielectric layer 153 (and the interfacial dielectric layer 151) are not present at the dummy gate metal 156. Accordingly, the dummy gate metal 156 is in direct contact with the channels 105b/c and the gate spacer layers 134. The gate dielectric layer can be removed during the removal of the gate metal 155 as described in relation to FIGS. 9A-9C.

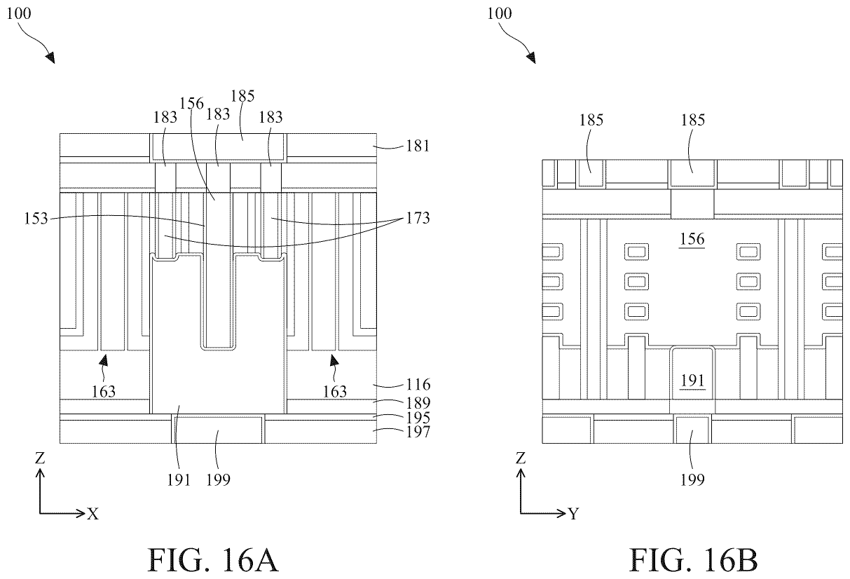

FIG. 16A is an X-view of the integrated circuit 100, in accordance with some embodiments. FIG. 16B is a Y-view of the integrated circuit 100 at the stage of processing of FIG. 16A, in accordance with some embodiments. The integrated circuit 100 of FIGS. 15A and 16B is substantially similar to the integrated circuit 100 of FIGS. 14A and 14B. One difference is that in FIGS. 16A and 16B, the dummy gate metal 156 is not substantially recessed during formation of the feedthrough via 191. Accordingly, the dimension D2 described in relation to FIG. 14B will be substantially zero in FIG. 16B. This can be achieved by using an etching process to form the trenches for the feedthrough via 191 that does not substantially etch the dummy gate metal 156.

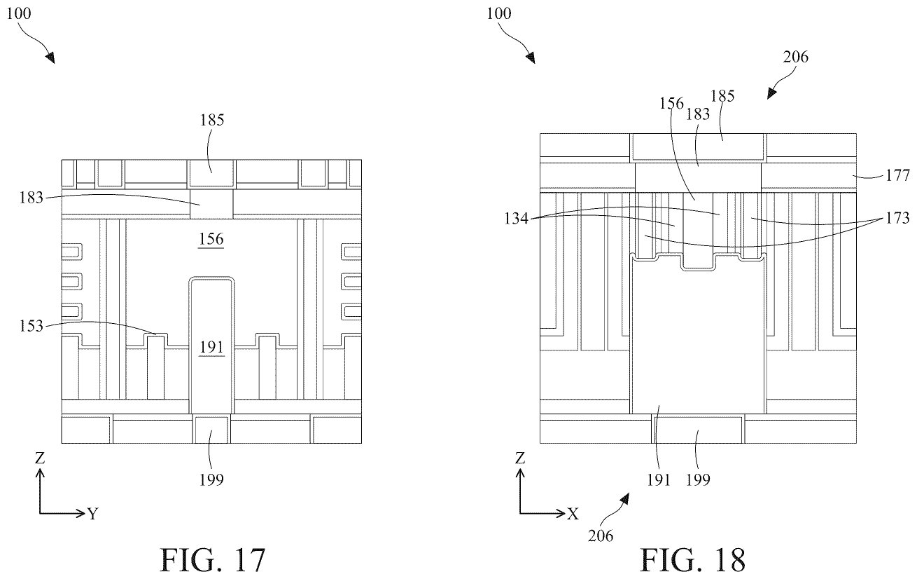

FIG. 17 is a Y-view of the integrated circuit 100, in accordance with some embodiments. In FIG. 17, the channels 105a/b have been removed. The channels 105a/b can be removed during removal of the gate metal 155 as described in relation to FIGS. 9A-9C. Accordingly, in FIG. 17, the dummy gate metal 156 does not surround any channels 105. This may further reduce the resistance of the feedthrough structure 206.

FIG. 18 is an X-view of the integrated circuit 100, in accordance with some embodiments. In FIG. 17, a single large conductive via 183 is formed in contact with the source/drain regions 173 and the dummy gate metal 156. This can be accomplished by patterning a single trench for the conductive vias 183 in the dielectric layer 177 at the stage of processing described in relation to FIGS. 12A-12C. This can further reduce the resistance of the feedthrough via structure 206.

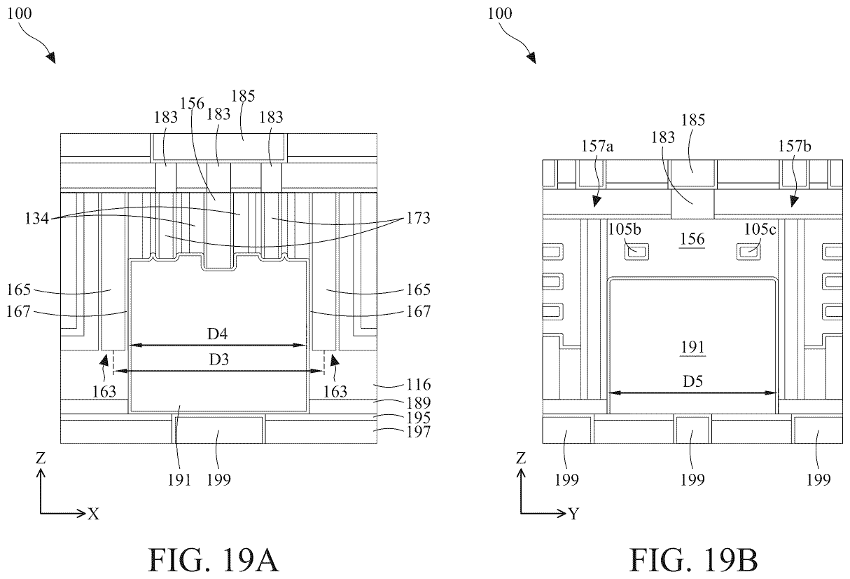

FIG. 19A is an X-view of the integrated circuit 100, in accordance with some embodiments. In FIG. 19A, the feedthrough via 191 has a dimension D4 in the X direction that is greater than in FIG. 14A and FIG. 19A, the etching process that forms the space for the feature via 191 etches a portion of the gate spacer layer 134 and corresponding liner layer. The result is that the feedthrough via 191 abuts the liner layer 167 of the CPODE structure 163. The dimension D4 is nearly equal to the dimension D3, corresponding to double the CPP. This results in a reduced resistance of the feedthrough via 191.

FIG. 19B is a Y-view of the integrated circuit 100 of FIG. 19A, in accordance with some embodiments. FIG. 19B illustrates that the width dimension D5 of the feature via 191 in the Y direction is substantially equal to the distance between the gate isolation structures 157a and 157b. This results in an overall lower resistance of the feedthrough via 191.

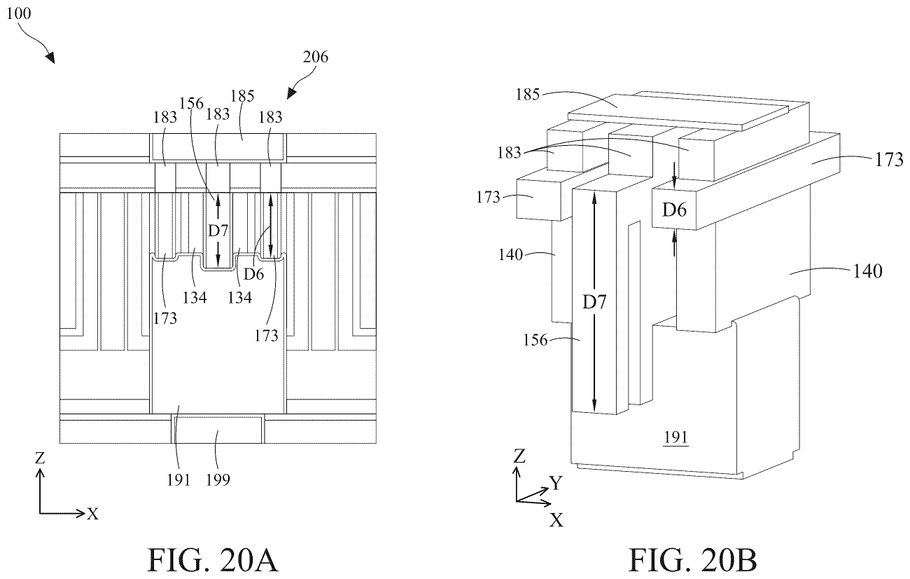

FIG. 20A is an X-view of the integrated circuit 100, in accordance with some embodiments. In FIG. 20A, the source/drain contacts 173 have a vertical dimension D6. The dummy gate metal 156 has a vertical dimension D7. In some embodiments, the vertical dimension D7 is slightly greater than the vertical dimension D6. The metal filler 156 extends to a same height as the source/drain regions 173. In some embodiments, the dimensions D6 and D7 are substantially equal. The conductive vias 183 can be merged into a single conductive via 183 as described in relation to FIG. 18.

FIG. 20B is a perspective view of the integrated circuit 100 of FIG. 20A, in accordance with some embodiments. The perspective view does not illustrate dielectric layers present in the integrated circuit 100. The perspective view of FIG. 20B illustrates source/drain regions 140, the dummy gate metal 156, source/drain contacts 173, conductive vias 183, the metal line 185, and the feedthrough via 191.

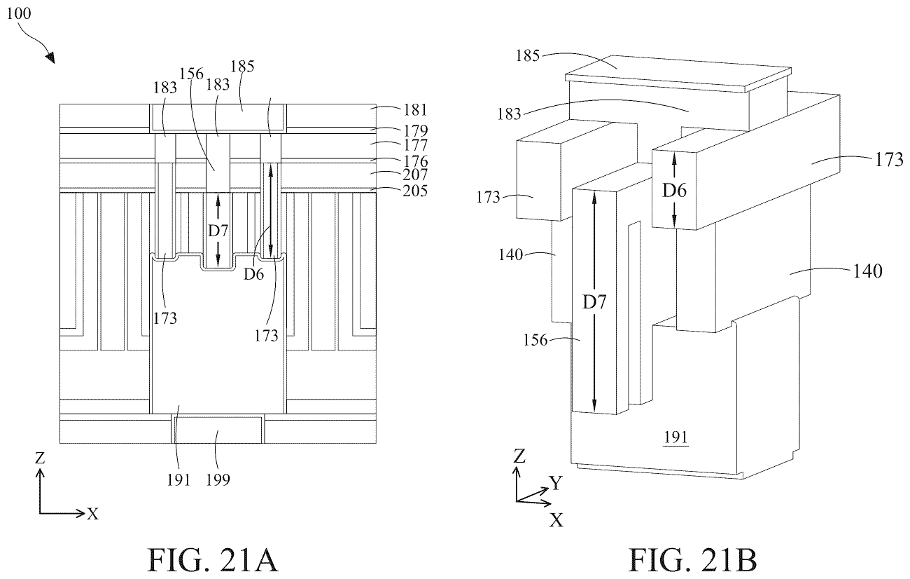

FIG. 21A is an X-view of the integrated circuit 100, in accordance with some embodiments. In FIG. 20 1A, dielectric layers 205 and 207 have been formed prior to formation of the source/drain contacts 173. The dielectric layers 205 and 207 may be substantially similar in composition to the dielectric layers 176 and 177, respectively. The conductive vias 183 are then formed through the dielectric layers 176 and 177. The conductive via 183 that contacts the dummy gate metal 156 extends through the dielectric layers 207 and 205. The result is that the vertical dimension D6 of the source/drain contacts 173 is greater than the vertical dimension D7 of the dummy gate metal 156. Furthermore, the source/drain contacts 173 extends to a greater height than does the dummy gate metal 156. The conductive vias 183 can be merged into a single conductive via 183 as described in relation to FIG. 18.

FIG. 21B is a perspective view of the integrated circuit 100 of FIG. 20A, in accordance with some embodiments. The perspective view does not illustrate dielectric layers present in the integrated circuit 100. The perspective view of FIG. 21B illustrates source/drain regions 140, the dummy gate metal 156, source/drain contacts 173, conductive vias 183, the metal line 185, and the feedthrough via 191. In FIG. 21B, the conductive vias 183 are merged into a single conductive via including a portion that protrudes downward to contact the dummy gate metal 156.

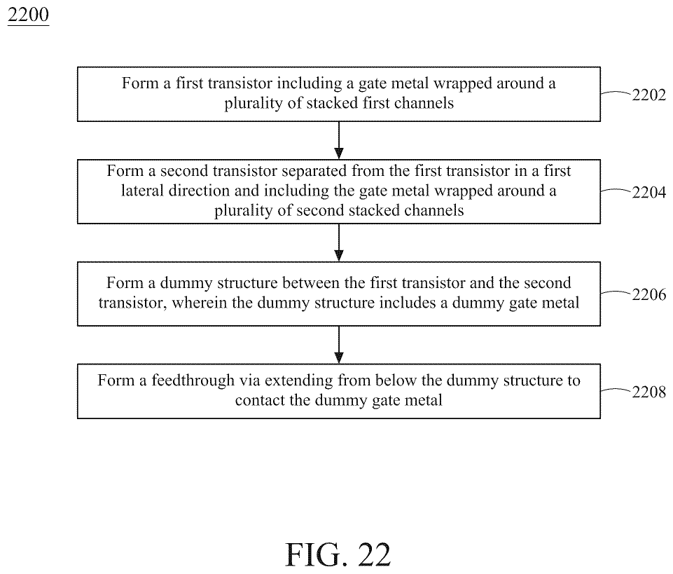

FIG. 22 is a flow diagram of a method 2200 for forming an integrated circuit, in accordance with some embodiments. The method 2200 can utilize the structures, processes, and systems described in relation to FIGS. 1-21B. At 2202, the method 2200 includes forming a first transistor including a gate metal wrapped around a plurality of stacked first channels. One example of a first transistor is the transistor 101a of FIG. 14A. One example of a gate metal is the gate metal 155 of FIG. 14A. One example of stacked first channels are the channels 105a of FIG. 14A. At 2204, the method 2200 includes forming a second transistor separated from the first transistor in a first lateral direction and including the gate metal wrapped around a plurality of second stacked channels. One example of a second transistor is the transistor 101d of FIG. 14A. One example of a gate metal is the gate metal 155 of FIG. 14A. One example of stacked second channels are the channels 105d of FIG. 14A. At 2206, the method 2200 includes forming a dummy structure between the first transistor and the second transistor, wherein the dummy structure includes a dummy gate metal. One example of a dummy structure is the dummy structure 101b of FIG. 14A. One example of a dummy gate metal is the dummy gate metal 156 of FIG. 14A. At 2208, the method 2200 includes forming a feedthrough via extending from below the dummy structure to contact the dummy gate metal. One example of the feedthrough via is the feedthrough via 191 of FIG. 14A.

Embodiments of the disclosure provide an integrated circuit with a feedthrough via structure that provides an electrical connection between the backside metal lines and front side metal lines of the integrated circuit. The feedthrough via structure merges source/drain contacts, a gate dummy gate metal, and source/drain conductive vias. The gate dummy gate metal is formed in place of a gate metal of a gate all around transistor structure positioned between two continuous polysilicon on the fusion edge (CPODE) structures. The result is a feedthrough cell with low area penalty and low resistance. This results in improved processing speeds and reduced power consumption.

In some embodiments, a method includes forming a first transistor including a gate metal wrapped around a plurality of stacked first channels and forming a second transistor separated from the first transistor in a first lateral direction and including the gate metal wrapped around a plurality of second stacked channels. The method includes forming a dummy structure between the first transistor and the second transistor, wherein the dummy structure includes a dummy gate metal with a lower resistivity than the gate metal and forming a feedthrough via extending from below the dummy structure to contact the dummy gate metal.

In some embodiments, an integrated circuit includes a substrate and a dummy transistor. The dummy transistor includes a dummy gate metal, a first dummy source/drain contact, and a second dummy source/drain contact. The integrated circuit includes a feedthrough via extending through the substrate and contacting the dummy gate metal, the first dummy source/drain contact, and the second dummy source/drain contact.

In some embodiments, an integrated circuit includes a first transistor including a gate metal and a second transistor including the gate metal. The integrated circuit includes a dummy transistor positioned between the first transistor and the second transistor and including a plurality of semiconductor nanostructures and a dummy gate metal surrounding the semiconductor nanostructures. The integrated circuit includes a backside feedthrough via in contact with a bottom of the dummy gate metal and a first metal line above the dummy gate metal and electrically connected to the backside feedthrough via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first transistor including a gate metal wrapped around a plurality of stacked first channels;
forming a second transistor separated from the first transistor in a first lateral direction and including the gate metal wrapped around a plurality of second stacked channels;
forming a dummy structure between the first transistor and the second transistor, wherein the dummy structure includes a dummy gate metal; and
forming a feedthrough via extending from below the dummy structure to contact the dummy gate metal.

2. The method of claim 1, wherein the dummy gate metal wraps around a plurality of stacked dummy channels.

3. The method of claim 1, wherein the forming the dummy structure includes:
depositing the gate metal around a plurality of stacked dummy channels of the dummy structure, around the first stacked channels, and around the second stacked channels;
removing the gate metal from the dummy structure; and
replacing the gate metal with the dummy metal at the dummy structure.

4. The method of claim 1, comprising:
forming a first dummy source/drain contact of the dummy structure;
forming a second dummy source/drain contact of the dummy structure; and
forming a first metal line over the dummy structure;
electrically shorting the first dummy source/drain contact, the second dummy source/drain contact, and the dummy gate metal to the first metal line.

5. The method of claim 4, wherein electrically shorting the first dummy source/drain contact, the second dummy source/drain contact, and the dummy gate metal to the first metal line includes forming a first conductive via coupled between the first dummy source/drain contact and the first metal line, forming a second conductive via coupled between the second dummy source/drain contact and the first metal line, and forming a third conductive via coupled between the dummy gate metal and the first metal line.

6. The method of claim 4, wherein electrically shorting the first dummy source/drain contact, the second dummy source/drain contact, and the dummy gate to the first metal line includes forming a conductive via in contact with the first dummy source/drain contact, the second dummy source/drain contact, the dummy gate metal, and the first metal line.

7. The method of claim 4, comprising forming a second metal line below and in contact with the feedthrough via.

8. The method of claim 4, wherein the feedthrough via is in contact with the first and second dummy source/drain structures.

9. The method of claim 1, comprising forming a gate isolation structure electrically isolating the gate metal of the first transistor and the dummy gate metal of the dummy structure.

10. The method of claim 1, comprising:
forming a first poly gate structure extending in the first lateral direction;
forming a second poly gate structure extending parallel to the first poly gate structure; and
forming the dummy gate metal and the feedthrough via between the first and second poly gate structures.

11. An integrated circuit, comprising:
a substrate;
a dummy structure including:
a dummy gate metal;
a first dummy source/drain contact; and
a second dummy source/drain contact; and
a feedthrough via extending through the substrate and contacting the dummy gate metal, the first dummy source/drain contact, and the second dummy source/drain contact.

12. The integrated circuit of claim 11, comprising:
a first transistor including a plurality of stacked first channels and a gate metal surrounding the stacked first channels; and
a second transistor separated from the first transistor in a first lateral direction including a plurality of stacked second channels and the gate metal surrounding the stacked second channels, the dummy structure being positioned between the first and second transistors, wherein the dummy gate metal has a lower resistivity than the gate metal.

13. The integrated circuit of claim 12, wherein the dummy gate transistor includes a plurality of stacked dummy channels, wherein the dummy gate metal wraps around the dummy channels.

14. The integrated circuit of claim 13, wherein the dummy gate metal is in direct contact with the dummy channels.

15. The integrated circuit of claim 11, wherein the dummy gate and the first and second dummy source/drain contacts extend to a same height.

16. The integrated circuit of claim 11, wherein the feedthrough via extends into the dummy gate metal.

17. The integrated circuit of claim 11, comprising:
a first metal line above the dummy structure;
a second metal line below and in contact with the feedthrough via; and
a conductive via between and in contact with the dummy gate metal and the first metal line.

18. An integrated circuit, comprising:
a first transistor including a gate metal;
a second transistor including the gate metal;
a dummy structure positioned between the first transistor and the second transistor and including a plurality of semiconductor nanostructures and a dummy gate metal surrounding the semiconductor nanostructures;
a backside feedthrough via in contact with a bottom of the dummy gate metal; and
a first metal line above the dummy gate metal and electrically connected to the backside feedthrough via.

19. The integrated circuit of claim 18, wherein the dummy structure includes first and second dummy source/drain contacts in contact with the backside feedthrough via.

20. The integrated circuit of claim 19, wherein the backside feedthrough via includes a U-shape in cross-section, wherein the dummy gate metal contacts the backside feedthrough via at a bottom of the U-shape, wherein the first and second dummy source/drain contacts contact the backside via at respective top ends of the U-shape.
